(19) United States
(12) Patent Application Publication
(10) Pub. No.: US 2026/0095170 A1
(43) Pub. Date: Apr. 2, 2026

(54) COMPARATOR CIRCUIT

(71) Applicants: Chongqing GigaChip Technology Co., Ltd., Chongqing (CN); NO.24 RESEARCH INSTITUTE OF CHINA ELECTRONICS TECHNOLOGY GROUP CORPORATION, Chongqing (CN)

(72) Inventors: Daiguo XU, Chongqing (CN); Dongbing FU, Chongqing (CN); Song YANG, Chongqing (CN); Xuebing LI, Chongqing (CN); Xingbing WU, Chongqing (CN); Jianan WANG, Chongqing (CN); Guangbing CHEN, Chongqing (CN); Zhou YU, Chongqing (CN); Zhengping ZHANG, Chongqing (CN); Can ZHU, Chongqing (CN); Lu LIU, Chongqing (CN); Haiyang YU, Chongqing (CN)

(73) Assignees: Chongqing GigaChip Technology Co., Ltd., Chongqing (CN); NO.24 RESEARCH INSTITUTE OF CHINA ELECTRONICS TECH, Chongqing (CN)

(21) Appl. No.: 19/412,768

(22) Filed: Dec. 8, 2025

Related U.S. Application Data
(63) Continuation of application No. PCT/CN2024/107270, filed on Jul. 24, 2024.

(30) Foreign Application Priority Data
Jun. 1, 2024 (CN) 202410702020.7

(51) Int. Cl. H03K 5/24

(52) U.S. Cl. CPC H03K 5/249; H03K 5/2481

(57) ABSTRACT

A comparator circuit includes: a first pre-amplification stage, which amplifies an input signal in the comparison state to generate a first output signal; a second pre-amplification stage, which switches between a reset state and a comparison state according to the first output signal, amplifies the first output signal in the comparison state to generate a second output signal, and provides positive feedback for the second output signal through a first positive feedback structure; and a latch stage, which, in the reset state, resets an output terminal of the latch stage to a second preset level according to the clock signal, and in the comparison state, controls a second positive feedback structure and a third positive feedback structure to be enabled through the second output signal and the clock signal to provide positive feedback to the output terminal.

### CROSS REFERENCE TO RELATED APPLICATION

The present disclosure is a continuation application of International Patent Application No. PCT/CN2024/107270, filed on Jul. 24, 2024, which claims the priority to Chinese Application No. 2024107020207 filed on Jun. 1, 2024, the contents of all of which are incorporated herein by reference in their entirety for all purposes.

### TECHNICAL FIELD

The present disclosure relates to the field of analog-to-digital conversion, and in particular to a comparator circuit.

### BACKGROUND

In recent years, with the continuous advancement of integrated circuit manufacturing technology, the feature size of CMOS devices has continued to decrease, and the operating voltage of integrated circuits has also continued to decrease. Under deep submicron processes, the operating speed of analog-to-digital converters has been greatly improved, while power consumption has been further reduced. However, as a core component of analog-to-digital converters, the performance of the comparator has become a bottleneck in the design of high-speed and low-power designs.

### SUMMARY

In view of the above problems existing in the conventional technique, the present disclosure proposes a comparator circuit, which mainly solves the problem that conventional comparators introduce more clock jitter and thus affect the accuracy of the comparator.

In order to achieve the above-mentioned and other purposes, the technical solutions adopted by the present disclosure are as follows.

The present application provides a comparator circuit, the comparator circuit includes: a first pre-amplification stage, which switches between a reset state and a comparison state according to a clock signal, cuts off an input signal and resets an output of the first pre-amplification stage to a first preset level in the reset state, and amplifies the input signal to generate a first output signal in the comparison state; a second pre-amplification stage including a first positive feedback structure, wherein the second pre-amplification stage switches between the reset state and the comparison state according to the first output signal, amplifies the first output signal in the comparison state to generate a second output signal, and provides positive feedback for the second output signal through the first positive feedback structure; and a latch stage connected to the second output signal and the clock signal, wherein the latch stage includes a second positive feedback structure and a third positive feedback structure, resets an output end of the latch stage to a second preset level according to the clock signal in the reset state, and uses the second output signal and the clock signal to control the second positive feedback structure and the third positive feedback structure to be turned on to provide positive feedback for the output end in the comparison state.

In an embodiment of the present application, the first pre-amplification stage includes: a zeroth transistor, a first transistor, a second transistor, a third transistor, and a fourth transistor, a gate of the zeroth transistor is connected to the clock signal, a source of the zeroth transistor is grounded, sources of the first transistor and the second transistor are respectively connected to a drain of the zeroth transistor, gates of the first transistor and the second transistor are respectively connected to a non-inverted signal and an inverted signal of the input signal, a drain of the first transistor is connected to a drain of the third transistor as a non-inverted output terminal of the first pre-amplification stage, a drain of the second transistor is connected to a drain of the fourth transistor as an auxiliary output terminal of the first pre-amplification stage, sources of the third transistor and the fourth transistor are connected to a power supply voltage, and gates of the third transistor and the fourth transistor are connected to the clock signal.

In an embodiment of the present application, the second pre-amplification stage includes: a fifth transistor, a sixth transistor, a seventh transistor, and an eighth transistor, sources of the fifth transistor and the sixth transistor are grounded, gates of the fifth transistor and the sixth transistor are respectively connected to a non-inverted signal and an inverted signal of the first output signal, a drain of the fifth transistor is connected to a drain of the seventh transistor as a non-inverted signal of the second output signal, a drain of the sixth transistor is connected to a drain of the eighth transistor as an inverted signal of the second output signal, gates of the seventh transistor and the eighth transistor are respectively connected to the inverted signal and the non-inverted signal of the first output signal, and sources of the seventh transistor and the eighth transistor are connected to the power supply voltage; wherein the fifth transistor, the sixth transistor, the seventh transistor, and the eighth transistor constitute the first positive feedback structure.

In an embodiment of the present application, the latch stage includes a ninth transistor, a tenth transistor, an eleventh transistor, a twelfth transistor, a thirteenth transistor, a fourteenth transistor, a fifteenth transistor, a sixteenth transistor, a seventeenth transistor, and an eighteenth transistor, sources of the ninth transistor and the tenth transistor are grounded, gates of the ninth transistor and the tenth transistor are connected to an inverted signal and a non-inverted signal of the second output signal respectively, drains of the ninth transistor and the tenth transistor are connected to sources of the twelfth transistor and the thirteenth transistor respectively, gates of the twelfth transistor and the sixteenth transistor are connected to drains of the thirteenth transistor and the seventeenth transistor as an inverted output terminal of the latch stage, drains of the twelfth transistor and the sixteenth transistor are connected to gates of the thirteenth transistor and the seventeenth transistor as a non-inverted output terminal of the latch stage, sources of the sixteenth transistor and the seventeenth transistor are connected to the power supply voltage, a gate of the fifteenth transistor is connected to the clock signal, a source of the fifteenth transistor is connected to the power supply voltage, and a drain of the fifteenth transistor is connected to the drain of the sixteenth transistor, a gate of the eighteenth transistor is connected to the clock signal, a source of the eighteenth transistor is connected to the power supply voltage, and a drain of the eighteenth transistor is connected to the drain of the seventeenth transistor, a source of the eleventh transistor is connected to the power supply voltage, a drain of the eleventh transistor serves as the non-inverted output terminal of the latch stage, and a gate of the eleventh transistor is connected to the inverted signal of the second output signal, a source of the fourteenth transistor is connected to the power supply voltage, a gate of the fourteenth transistor is connected to the non-inverted signal of the second output signal, and a drain of the fourteenth transistor serves as an inverted output terminal of the latch stage, and the eleventh transistor and the fourteenth transistor form the second positive feedback structure, and the twelfth transistor, the thirteenth transistor, the sixteenth transistor and the seventeenth transistor form the third positive feedback structure.

In an embodiment of the present application, the number of NMOS transistors in a path from the power supply voltage to the ground in the latch stage is greater than the number of PMOS transistors therein.

In an embodiment of the present application, the zeroth transistor, the first transistor, the second transistor, the fifth transistor, the sixth transistor, the ninth transistor, the tenth transistor, the twelfth transistor, and the thirteenth transistor are all NMOS transistors; and the third transistor, the fourth transistor, the seventh transistor, the eighth transistor, the eleventh transistor, the fourteenth transistor, the fifteenth transistor, the sixteenth transistor, the seventeenth transistor, and the eighteenth transistor are all PMOS transistors.

As described above, the comparator circuit proposed in one or more embodiments of this application has the following beneficial effects.

The second pre-amplification stage is completely controlled by the output signal of the first pre-amplification stage, which reduces the number of transistors connected to the clock signal, thereby suppressing clock signal jitter and effectively improving the accuracy of the comparator. In addition, a positive feedback structure is provided in the second pre-amplification stage and the latch stage, increasing the number of positive feedback loops, which can effectively improve the comparison speed of the comparator.

### BRIEF DESCRIPTION OF DRAWINGS

FIG. 1 is a schematic diagram of a structure of a conventional comparator.

FIG. 2 is a schematic diagram of a structure of a conventional improved comparator.

FIG. 3 is a schematic block diagram of a structure of a comparator circuit in an embodiment of the present application.

FIG. 4 is a schematic diagram of a comparator circuit in an embodiment of the present application.

FIG. 5 is a comparison diagram of comparison delay simulation of three comparator circuits in FIGS. 1, 2, and 4 as input signal amplitude changes.

FIG. 6 is a comparison diagram of reset delay simulations of three comparator circuits in FIGS. 1, 2, and 4 as power supply voltage changes.

FIG. 7 is a comparison diagram of noise simulations of three comparator circuits in FIGS. 1, 2, and 4 as input common-mode voltage changes.

### DESCRIPTION OF EMBODIMENTS

The embodiments of the present disclosure are described below by way of specific examples. Those skilled in the art can easily understand other advantages and effects of the present disclosure from the content disclosed in this specification. The present disclosure can also be implemented or applied through other different specific embodiments. The details in this specification can also be modified or changed based on different viewpoints and applications without departing from the present disclosure. It should be noted that the following embodiments and features in the embodiments can be combined with each other unless they conflict.

It should be noted that the illustrations provided in the following embodiments are merely schematic illustrations of the basic concept of the present disclosure. Therefore, the illustrations only show components related to the present disclosure and are not drawn according to the number, shape, and size of components in actual implementation. In actual implementation, the type, quantity, and scale of each component may be changed arbitrarily, and the component layout may also be more complex.

The inventors have found that the conventional comparator structure has the following problems.

Several conventional comparator structures have difficulty in simultaneously meeting the requirements of speed, power consumption, and low supply voltage.

For the conventional comparator structure, the clock signal always appears in each stage of the comparator, which will introduce large clock jitter to each stage of the comparator, resulting in large noise. In addition, the layout clock routing is relatively complex, and the accuracy of the comparator is greatly limited.

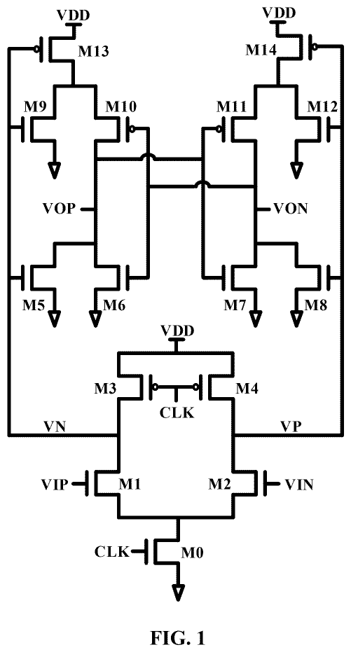

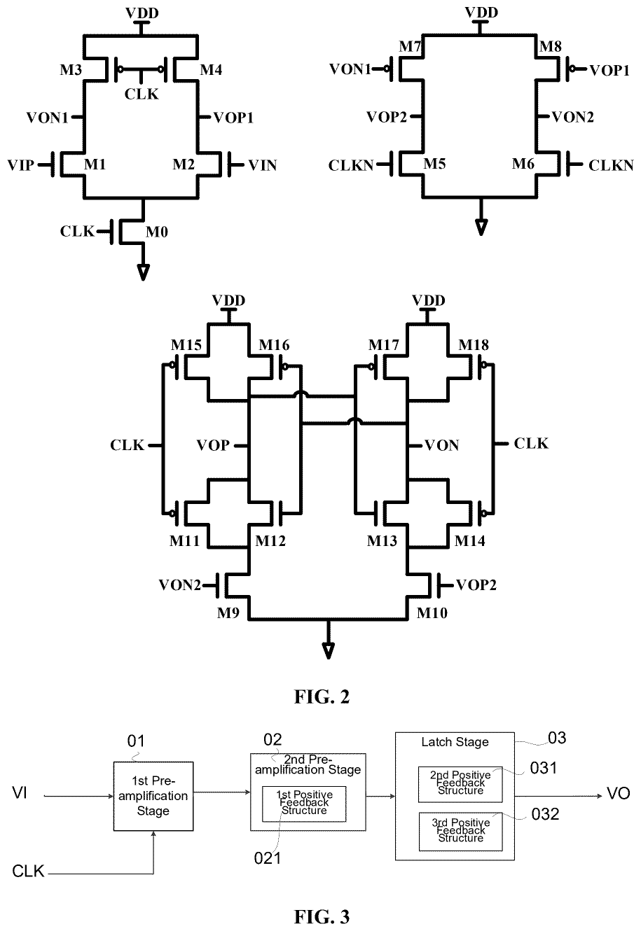

In applications with lower precision requirements, a single-stage latch structure can be used as the comparator. This structure has the advantages of high speed and low power consumption. However, it has the disadvantages of high noise and offset. In applications with higher precision requirements, to mitigate the high noise and offset drawbacks of the single-stage latch structure, the comparator typically has a structure where multiple pre-amplification stages are first cascaded and then connected to a latch stage. The conventional comparator structure is shown in FIG. 1. The pre-amplification stage includes NMOS transistors M0, M1, M2, and PMOS transistors M3 and M4. The latch stage includes NMOS transistors M5, M6, M7, M8, M9, M12, and PMOS transistors M10, M11, M13, and M14. When the clock signal CLK is at a low level, the comparator is in a reset state where M0 in the pre-amplification stage is off, and M3 and M4 are on. The output signals VP and VN of the pre-amplification stage are reset to a high level. In the latch stage, M5, M8, M9, and M12 are turned on, while M13 and M14 are turned off. Therefore, the latch's output signals VOP and VON are reset to a low level. When the clock signal CLK is at a high level, the comparator enters the comparison state where M0 turns on, and the pre-amplification stage amplifies the input signals VIP and VIN. In the latch stage, M5, M8, M9, and M12 are turned off, while M13 and M14 are turned on. This activates the positive feedback loop formed by latches M6, M7, M10, and M11, latching the pre-amplification stage's output signals VP and VN, generating high-level and low-level signals VOP and VON, completing the comparison process. A problem with this structure is that the latch stage has three MOS transistors connected from power to ground, resulting in a high impedance from power to ground. Furthermore, two of these three MOS transistors are PMOS transistors, further increasing latch delay. To address these issues, existing solutions propose an improved comparator structure, as shown in FIG. 2. This structure includes two pre-amplification stages and one latch stage. The first pre-amplification stage includes NMOS transistors M0, M1, M2, and PMOS transistors M3 and M4. The second pre-amplification stage includes NMOS transistors M5, M6, and PMOS transistors M7 and M8. The latch stage includes NMOS transistors M9, M10, M12, M13, and PMOS transistors M11, M14, M15, M16, M17, and M18. Signal CLKN is the inverted signal of signal CLK. When clock signal CLK is low, CLKN is high. The comparator is in the reset state, the output signals VOP1 and VON1 of the first pre-amplification stage are high. M5 and M6 in the second pre-amplification stage are turned on, and M7 and M8 are turned off. Therefore, VOP2 and VON2 are at a low level, M9 and M10 in the latch stage are turned off, and M11, M14, M15, and M18 are turned on. Therefore, the output signals VOP and VON of the latch are reset to a high level. When the clock signal CLK becomes high, CLKN is low. The comparator is in the comparison state, M0 is on, and the first pre-amplification stage amplifies the input signals VIP and VIN, gradually decreasing VOP1 and VON1 from a high level. In the second pre-amplification stage, M5 and M6 are off, and the second pre-amplification stage amplifies the output signals VOP1 and VON1 of the first pre-amplification stage, gradually increasing VOP2 and VON2 from a low level. The pre-amplification results VOP2 and VON2 of the second pre-amplification stage are output to the latch stage. In the latch stage, M9 and M10 are on, M11, M14, M15, and M18 are off, and the positive feedback loop formed by M12, M13, M16, and M17 is activated, generating high-level and low-level signals VOP and VON, completing the comparison process. The structure shown in FIG. 2 uses a structure of two pre-amplification stages, which increases the accuracy of the comparator. In the latch stage, there are two NMOS transistors and one PMOS transistor between the power supply and ground, which improves the speed of the comparator compared to the structure shown in FIG. 1. However, the problem with the structure shown in FIG. 2 is that both the pre-amplification stages and the latch stage require clock signals for control, which increases routing complexity and affects the accuracy of the comparator. In addition, there is still only one positive feedback structure, and the speed of the comparator still has room for improvement.

In view of the above problems existing in the conventional technique, the present application proposes a comparator circuit, and the comparator circuit of the present application is described in detail below with reference to specific embodiments.

Please refer to FIG. 3, which is a schematic block diagram of a structure of a comparator circuit in an embodiment of the present application. The comparator circuit of the embodiment of the present application includes: a first pre-amplification stage 01, a second pre-amplification stage 02, and a latch stage 03. The first pre-amplification stage 01 switches between a reset state and a comparison state according to a clock signal, in the reset state, the input signal is cut off, and the output of the first pre-amplification stage 01 is reset to a first preset level, and in the comparison state, the input signal is amplified to generate a first output signal. The second pre-amplification stage 02 includes a first positive feedback structure 021, the second pre-amplification stage 02 switches between a reset state and a comparison state according to the first output signal, in the comparison state the first output signal is amplified to generate a second output signal, and positive feedback is provided for the second output signal through the first positive feedback structure 021 The latch stage 03 receives the second output signal and the clock signal. The latch stage includes a second positive feedback structure 031 and a third positive feedback structure 032, in the reset state, the output end of the latch stage 03 is reset to a second preset level according to the clock signal, and in the comparison state the second positive feedback structure 031 and the third positive feedback structure 032 are controlled to be turned on by the second output signal and the clock signal to provide positive feedback to the output end. Specifically, in the comparison state, the first pre-amplification stage 01 amplifies the input signal under the control of the clock signal, generates a first output signal, and outputs the first output signal to the second pre-amplification stage 02. The second pre-amplification stage 02 may include two sets of input terminals, the two sets of input terminals each are connected to the first output signal. Under the control of the first output signal, the second pre-amplification stage 02 generates a second output signal and transmits the second output signal to the latch stage 03. Because the second pre-amplification stage 02 is directly controlled by the output of the first pre-amplification stage 01, and no additional clock signal is input, the jitter introduced by the clock signal can be reduced, thereby lowering noise.

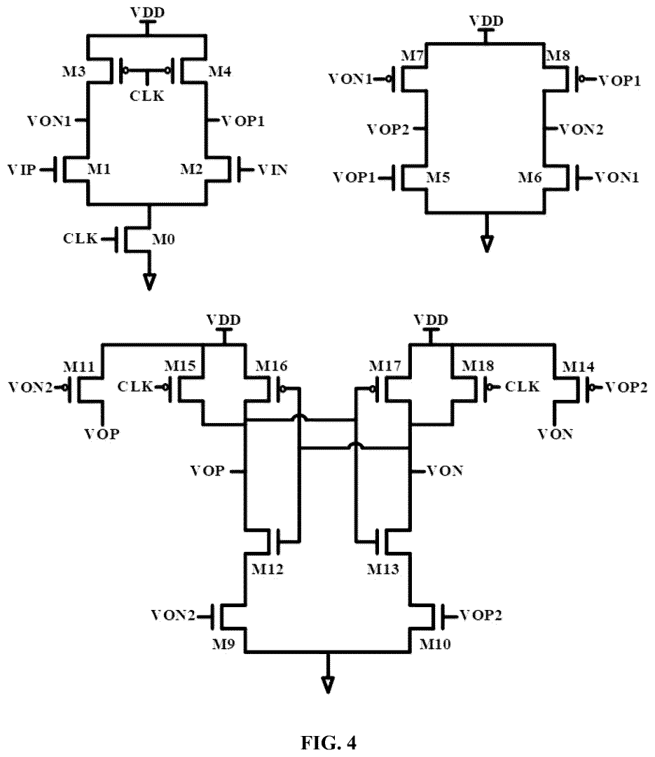

Please refer to FIG. 4, which is a schematic diagram of a comparator circuit according to an embodiment of the present application. In an embodiment, the first pre-amplification stage includes: a zeroth transistor M0, a first transistor M1, a second transistor M2, a third transistor M3, and a fourth transistor M4. The gate of the zeroth transistor M0 is connected to the clock signal, the source of the zeroth transistor M0 is grounded, and the sources of the first transistor M1 and the second transistor M2 are respectively connected to the drain of the zeroth transistor M0. The gates of the first transistor M1 and the second transistor M2 are respectively connected to the non-inverted signal VIP and the inverted signal VIN of the input signal. The drain of the first transistor M1 is connected to the drain of the third transistor M3 as the non-inverted output terminal VOP1 of the first pre-amplification stage, the drain of the second transistor M2 is connected to the drain of the fourth transistor M4 as the auxiliary output terminal VON1 of the first pre-amplification stage, the sources of the third transistor M3 and the fourth transistor M4 are connected to the power supply voltage VDD, and the gates of the third transistor M3 and the fourth transistor M4 are connected to the clock signal CLK. Specifically, the first pre-amplification stage is composed of NMOS transistors M0, M1, M2, and PMOS transistors M3 and M4, where the sources of M1 and M2 are grounded, and the gates of M1 and M2 are connected to the input signals VIP and VIN respectively, the drains of M1 and M2 are connected to the drains of M3 and M4 respectively, the gates of M3 and M4 are connected to the clock signal CLK, the sources of M3 and M4 are connected to the power supply VDD, and VOP1 and VON1 are the output signals of the first pre-amplification stage.

In one embodiment, the second pre-amplification stage includes: a fifth transistor M5, a sixth transistor M6, a seventh transistor M7, and an eighth transistor M8; the sources of the fifth transistor M5 and the sixth transistor M6 are grounded, the gates of the fifth transistor M5 and the sixth transistor M6 are respectively connected to the non-inverted signal VOP1 and the inverted signal VON1 of the first output signal, the drain of the fifth transistor M5 is connected to the drain of the seventh transistor M7 as the non-inverted signal VOP2 of the second output signal, the drain of the sixth transistor M6 is connected to the drain of the eighth transistor M8 as the inverted signal VON2 of the second output signal, the gates of the seventh transistor M7 and the eighth transistor M8 are respectively connected to the inverted signal VON1 and the non-inverted signal VOP1 of the first output signal, and the sources of the seventh transistor M7 and the eighth transistor M8 are connected to the power supply voltage VDD; wherein the fifth transistor M5 to the eighth transistor M8 form the first positive feedback structure. Specifically, the second pre-amplification stage includes the NMOS transistors M5 and M6, and the PMOS transistors M7 and M8, wherein the sources of M5 and M6 are grounded, and the gates of M5 and M6 are respectively connected to the output signals VOP1 and VON1 of the first pre-amplification stage, the drains of M5 and M6 are respectively connected to the drains of M7 and M8, the gates of M7 and M8 are respectively connected to the output signals VON1 and VOP1 of the first pre-amplification stage, the sources of M7 and M8 are connected to the power supply VDD, and VOP2 and VON2 are the output signals of the second pre-amplification stage.

In an embodiment, the latch stage includes a ninth transistor M9, a tenth transistor M10, an eleventh transistor M11, a twelfth transistor M12, a thirteenth transistor M13, a fourteenth transistor M14, a fifteenth transistor M15, a sixteenth transistor M16, a seventeenth transistor M17, and an eighteenth transistor M18; the sources of the ninth transistor M9 and the tenth transistor M10 are grounded, the gates of the ninth transistor M9 and the tenth transistor M10 are connected to the inverted signal VON2 and the non-inverted signal VOP2 of the second output signal, respectively; the drains of the ninth transistor M9 and the tenth transistor M10 are connected to the sources of the twelfth transistor M12 and the thirteenth transistor M13, respectively; the gates of the twelfth transistor M12 and the sixteenth transistor M16 are connected to the drains of the thirteenth transistor M13 and the seventeenth transistor M17 as the inverted output terminal VON of the latch stage; the drains of the twelfth transistor M12 and the sixteenth transistor M16 are connected to the gates of the thirteenth transistor M13 and the seventeenth transistor M17 as the non-inverted output terminal VOP of the latch stage, the sources of the sixteenth transistor M16 and the seventeenth transistor M17 are connected to the power supply voltage VDD, the gate of the fifteenth transistor M15 is connected to the clock signal CLK, the source of the fifteenth transistor M15 is connected to the power supply voltage VDD, the drain of the fifteenth transistor M15 is connected to the drain of the sixteenth transistor M16; the gate of the eighteenth transistor M18 is connected to the clock signal CLK, the source of the eighteenth transistor M18 is connected to the power supply voltage VDD, and the drain of the eighteenth transistor M18 is connected to the drain of the seventeenth transistor M17; the source of the eleventh transistor M11 is connected to the power supply voltage VDD, the drain of the eleventh transistor M11 serves as the non-inverted output terminal VOP of the latch stage, the gate of the eleventh transistor M11 is connected to the inverted signal VON2 of the second output signal, the source of the fourteenth transistor M14 is connected to the power supply voltage VDD, and the gate of the fourteenth transistor M14 is connected to the non-inverted signal VOP2 of the second output signal; the drain of the fourteenth transistor M14 serves as the inverted output terminal VON of the latch stage; wherein the eleventh transistor M11 and the fourteenth transistor M14 constitute the second positive feedback structure; the twelfth transistor M12, the thirteenth transistor M13, the sixteenth transistor M16 and the seventeenth transistor M17 constitute the third positive feedback structure. Specifically, the latch stage includes transistors M9-M18, wherein the sources of NMOS transistors M9 and M10 are grounded, and the gates of M9 and M10 are connected to the output signals VON2 and VOP2 of the second-stage pre-amplifier, respectively, the drains of M9 and M10 are connected to the sources of NMOS transistors M12 and M13, respectively, NMOS transistors M12, M13, and PMOS transistors M16 and M17 form two back-to-back inverter structures connected end-to-end. VOP and VON are the output signals of the latch stage. The drains of PMOS transistors M15 and M18 are connected to the drains of M16 and M17, respectively, the sources of M15 and M18 are connected to the power supply VDD, and the gates of M15 and M18 are connected to the clock signal CLK, the sources of PMOS transistors M11 and M14 are connected to the power supply VDD, the gates of M11 and M14 are connected to the output signals VON2 and VOP2 of the second-stage latch, respectively, and the drains of M11 and M14 are connected to the latch output signals VOP and VON, respectively.

The comparator circuit of the present embodiment operates as follows. When the clock signal CLK is low, the comparator is in a reset state. M3 and M4 in the first pre-amplification stage are turned on, and VOP1 and VON1 are reset to a high level. Consequently, NMOS transistors M5 and M6 in the second pre-amplification stage are turned on, while PMOS transistors M7 and M8 are turned off. The output signals VOP2 and VON2 of the second pre-amplification stage are reset to a low level. Since the input transistors of the latch stage are NMOS transistors M9 and M10, M9 and M10 are turned off in the reset state. Furthermore, since the gates of PMOS transistors M15 and M18 are connected to the clock signal CLK, M15 and M18 are turned on. Furthermore, since the gates of PMOS transistors M11 and M14 are connected to VOP2 and VON2, respectively, M11 and M14 are both turned on, and thus the output signals VOP and VON are reset to a high level. When the clock signal CLK becomes high, the comparator enters a comparison state. In the first pre-amplification stage, M3 and M4 are turned off, and the input signals VIP and VIN are amplified by the first pre-amplification stage, generating the output signals VOP1 and VON1 of the first pre-amplification stage. Furthermore, VOP1 and VON1 gradually decrease from the power supply voltage VDD. As VOP1 and VON1 gradually decrease from the power supply voltage VDD, NMOS transistors M5 and M6 in the second pre-amplification stage gradually turn off, and PMOS transistors M7 and M8 gradually turn on, generating the output signals VOP2 and VON2 of the second pre-amplification stage. At the same time, VOP2 and VON2 gradually increase from 0. It should be noted that, since the gates of the NMOS transistor M5 and the PMOS transistor M8 are connected to VOP1, and the gates of the NMOS transistor M6 and the PMOS transistor M7 are connected to VON1, the structures of M5, M6, M7 and M8 in the second pre-amplification stage form a first positive feedback structure. Compared with the conventional structure shown in FIG. 2, this first positive feedback structure significantly improves the comparison speed of the second pre-amplification stage. Furthermore, since the input signals of the second pre-amplification stage are all the output signals of the first pre-amplification stage and no clock is input to the second pre-amplification stage, noise generated by clock jitter will not be introduced into the second pre-amplification stage, thereby improving the accuracy of the comparator. Since VOP2 and VON2 gradually increase from 0 to VDD in the comparison state, M9 and M10 in the latch stage are gradually turned on, and the clock signal CLK of the gates of the PMOS transistors M15 and M18 is at a high level in the comparison state. Therefore, M15 and M18 are both turned off in the comparison state, and the third positive feedback structure including the NMOS transistors M12 and M13 and the PMOS transistors M16 and M17 latches the input signal of the latch; furthermore, the PMOS transistors M11 and M14 form another positive feedback structure (i.e., the second positive feedback structure). Compared with the structure shown in FIG. 2, since there is one positive feedback loop in the second pre-amplification stage, the latch has two positive feedback loops, which further improve the speed of the comparator. In addition, the clock signal CLK in the latch stage is only connected to the gates of M15 and M18, while in the structure shown in FIG. 2, the clock signal CLK is connected to the gates of the PMOS transistors M11, M14, M15, and M18. Compared with the structure shown in FIG. 2, the load capacitance that the clock signal needs to drive in the embodiment of the present application is reduced by half, thereby improving the speed of the latch.

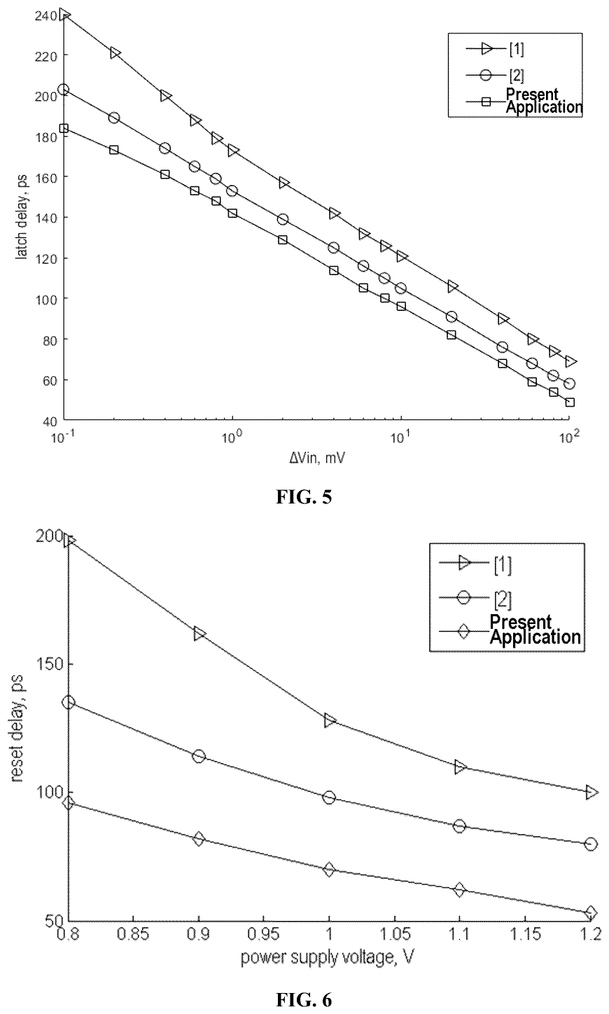

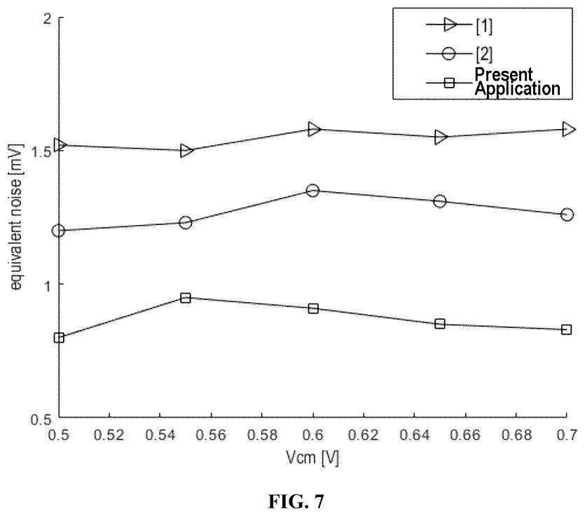

The following is a verification of the three comparator structures shown in FIGS. 1-3. To effectively demonstrate the effectiveness of the embodiments of the present application, the transistors in all three structures are manufactured using a 65 nm CMOS process. The three comparator structures use the same input/output transistor sizes, the same latch stage sizes, and 15 fF load capacitance. The clock frequency is 2 GHZ, the power supply voltage is 1.2V, and the common-mode voltage is 0.6V. During the latching process, the comparator is considered to have latched when |VOP-VON|=0.6V. A comparison curve of the latch delay of the three comparators as a function of the input differential signal ΔVin is shown in FIG. 5. As shown in FIG. 5, the latch delay of the comparator shown in the present disclosure is reduced by at least 22%. The clock frequency is 2 GHZ, the input differential signal ΔVin is set to 50 mV, and the comparator is considered to have reset when both VOP and VON are greater than 0.5 VDD. The comparison curves of the reset delay of the three comparators as a function of the power supply voltage are shown in FIG. 6. As can be seen from FIG. 6, the latch delay of the comparator of the present disclosure is reduced by at least 38%. The comparison curves of the equivalent noise of the three comparators as a function of the input common mode voltage (Vcm) are shown in FIG. 7. As can be seen from FIG. 7, the equivalent noise of the comparator shown in the present disclosure is reduced by at least 41%.

The present application reduces the number of transistors connected to the clock signal, thereby suppressing clock signal jitter, and can effectively improve the accuracy of the comparator.

The above embodiments are merely illustrative of the principles and effects of the present disclosure and are not intended to limit the present disclosure. Anyone skilled in the art may modify or alter the above embodiments without departing from the scope of the present disclosure. Therefore, all equivalent modifications or alterations made by one of ordinary skill in the art are intended to be covered by the claims of the present disclosure.

What is claimed is:

1. A comparator circuit, comprising:
a first pre-amplification stage configured to switch between a reset state and a comparison state according to a clock signal, cut off an input signal and reset an output of the first pre-amplification stage to a first preset level in the reset state, and amplify the input signal to generate a first output signal in the comparison state;
a second pre-amplification stage including a first positive feedback structure, wherein the second pre-amplification stage is configured to switch between the reset state and the comparison state according to the first output signal, amplify the first output signal in the comparison state to generate a second output signal, and provide positive feedback for the second output signal through the first positive feedback structure; and
a latch stage connected to the second output signal and the clock signal, wherein the latch stage includes a second positive feedback structure and a third positive feedback structure and is configured to reset an output end of the latch stage to a second preset level according to the clock signal in the reset state, and use the second output signal and the clock signal to control the second positive feedback structure and the third positive feedback structure to be turned on to provide positive feedback for the output end in the comparison state.

2. The comparator circuit according to claim 1, wherein:
the first pre-amplification stage includes: a zeroth transistor, a first transistor, a second transistor, a third transistor, and a fourth transistor,
a gate of the zeroth transistor is connected to the clock signal, and a source of the zeroth transistor is grounded,
sources of the first transistor and the second transistor are respectively connected to a drain of the zeroth transistor,
gates of the first transistor and the second transistor are respectively connected to a non-inverted signal and an inverted signal of the input signal,
a drain of the first transistor is connected to a drain of the third transistor as a non-inverted output terminal of the first pre-amplification stage,
a drain of the second transistor is connected to a drain of the fourth transistor as an auxiliary output terminal of the first pre-amplification stage,
sources of the third transistor and the fourth transistor are connected to a power supply voltage, and
gates of the third transistor and the fourth transistor are connected to the clock signal.

3. The comparator circuit according to claim 2, wherein:
the second pre-amplification stage includes: a fifth transistor, a sixth transistor, a seventh transistor, and an eighth transistor,
sources of the fifth transistor and the sixth transistor are grounded,
gates of the fifth transistor and the sixth transistor are respectively connected to a non-inverted signal and an inverted signal of the first output signal,
a drain of the fifth transistor is connected to a drain of the seventh transistor as a non-inverted signal of the second output signal,
a drain of the sixth transistor is connected to a drain of the eighth transistor as an inverted signal of the second output signal,
gates of the seventh transistor and the eighth transistor are respectively connected to the inverted signal and the non-inverted signal of the first output signal, and
sources of the seventh transistor and the eighth transistor are connected to the power supply voltage; wherein the fifth transistor, the sixth transistor, the seventh transistor, and the eighth transistor constitute the first positive feedback structure.

4. The comparator circuit of claim 3, wherein:
the latch stage includes a ninth transistor, a tenth transistor, an eleventh transistor, a twelfth transistor, a thirteenth transistor, a fourteenth transistor, a fifteenth transistor, a sixteenth transistor, a seventeenth transistor, and an eighteenth transistor,
sources of the ninth transistor and the tenth transistor are grounded,
gates of the ninth transistor and the tenth transistor are connected to the inverted signal and the non-inverted signal of the second output signal, respectively,
drains of the ninth transistor and the tenth transistor are connected to sources of the twelfth transistor and the thirteenth transistor, respectively,
gates of the twelfth transistor and the sixteenth transistor are connected to drains of the thirteenth transistor and the seventeenth transistor as an inverted output terminal of the latch stage,
drains of the twelfth transistor and the sixteenth transistor are connected to gates of the thirteenth transistor and the seventeenth transistor as a non-inverted output terminal of the latch stage,
sources of the sixteenth transistor and the seventeenth transistor are connected to the power supply voltage,
a gate of the fifteenth transistor is connected to the clock signal, a source of the fifteenth transistor is connected to the power supply voltage, and a drain of the fifteenth transistor is connected to the drain of the sixteenth transistor,
a gate of the eighteenth transistor is connected to the clock signal, a source of the eighteenth transistor is connected to the power supply voltage, and a drain of the eighteenth transistor is connected to the drain of the seventeenth transistor,
a source of the eleventh transistor is connected to the power supply voltage, a drain of the eleventh transistor serves as the non-inverted output terminal of the latch stage, and a gate of the eleventh transistor is connected to the inverted signal of the second output signal,
a source of the fourteenth transistor is connected to the power supply voltage, a gate of the fourteenth transistor is connected to the non-inverted signal of the second output signal, and a drain of the fourteenth transistor serves as the inverted output terminal of the latch stage, and
the eleventh transistor and the fourteenth transistor form the second positive feedback structure, and the twelfth transistor, the thirteenth transistor, the sixteenth transistor, and the seventeenth transistor form the third positive feedback structure.

5. The comparator circuit according to claim 4, wherein a number of NMOS transistors in a path from the power supply voltage to the ground in the latch stage is greater than a number of PMOS transistors in the path from the power supply voltage to the ground in the latch stage.

6. The comparator circuit according to claim 5, wherein:
the zeroth transistor, the first transistor, the second transistor, the fifth transistor, the sixth transistor, the ninth transistor, the tenth transistor, the twelfth transistor, and the thirteenth transistor are all NMOS transistors; and
the third transistor, the fourth transistor, the seventh transistor, the eighth transistor, the eleventh transistor, the fourteenth transistor, the fifteenth transistor, the sixteenth transistor, the seventeenth transistor, and the eighteenth transistor are all PMOS transistors.
